(19) United States
(12) Patent Application Publication
(10) Pub. No.: US 2010/0110628 A1
(43) Pub. Date: May 6, 2010

(54) Apparatus and Method for Enhancing the Maintainability and Cooling of Computer Components on Trays in a Cabinet

(76) Inventors: Mark Barrenechea, Berkeley, CA (US); Giovanni Coglitore, Saratoga, CA (US); Conor Malone, Cupertino, CA (US); Richard Huang, Palo Alto, CA (US)

Correspondence Address: COOLEY GODWARD KRONISH LLP;ATTN: Patent Group, Suite 1100, 777 - 6th Street, NW, WASHINGTON, DC, 20001, US

(21) Appl. No.: 12/609,613

(22) Filed: Oct. 30, 2009

Related U.S. Application Data
(60) Provisional application No. 61/109,818, filed on Oct. 30, 2008.

(51) Int. Cl. G06F 1/16; G06F 1/20; B23P 6/00; H05K 7/14

(52) U.S. Cl. 361/679.48; 361/679.02; 29/897.1; 361/727

(57) ABSTRACT

A computer system includes a cabinet, a first port mounted on a rear panel of the cabinet, and a tray mounted in the cabinet and having computer components mounted thereon. A front panel of the tray faces outward from a front side of the cabinet opposite the rear panel. The computer system further includes a second port mounted on the front panel of the tray, and a first cable that electrically couples the first port and the second port. The first cable is routed within the cabinet and protrudes from the front side of the cabinet. The first port also remains coupled to the second port as the tray slides outwards from the front side of the cabinet so that the computer components substantially protrude from the front side of the cabinet. The first port and the second port are for at least one of electrical power and network connectivity.

### CROSS-REFERENCE TO RELATED APPLICATIONS

This application claims priority to U.S. Provisional Application Ser. No. 61/109,818, filed Oct. 30, 2008, entitled “Apparatus and Method for Enhancing the Maintainability and Cooling of Computer Components on Trays in a Cabinet,” the disclosure of which is incorporated herein by reference in its entirety.

### FIELD OF THE INVENTION

The present invention relates generally to the manner in which computer components are designed, configured, and installed in a given area. More particularly, this invention relates to enhancing the maintainability and cooling of computer components mounted on trays in a cabinet.

### BACKGROUND OF THE INVENTION

As information technology has rapidly progressed, computer network centers such as server farms and server clusters have become increasingly important to our society. The server farms provide efficient data processing, storage, and distribution capability that supports a worldwide information infrastructure, which has come to alter how we live and how we conduct our day to day business.

At a site where numerous computers are connected to a network, the computers and related equipment arc often stacked in racks. Many of the racks are filled with cumbersome computers mounted on sliders, which are attached through mounting holes provided in the front and back of the rack. Each of these computers is often also housed in a chassis. It can be inconvenient to service and/or upgrade components of these computers because a computer may need to be dismounted from a rack, and a portion of the chassis housing the computer may need to be disassembled. In addition, to service and/or upgrade a component of these computers, the entire computer may need to be taken out of service.

Moreover, the form factor of computers is becoming progressively smaller. For example, for computer chassis with a 1U height (1.75″), approximately 1U-sized fans are typically installed inside the chassis. As compared to larger fans typically used in chassis housing computers with larger form factors, these small fans may be mechanically unreliable and may also have significantly less air moving ability, which may impact both the maintainability and cooling of computers with a small form factor.

In view of the foregoing problems, it would be desirable to provide techniques for enhancing the maintainability and cooling of computer components mounted on trays in a cabinet.

### SUMMARY OF THE INVENTION

In one innovative aspect, the invention relates to a computer system comprising a cabinet, a first port mounted on a rear panel of the cabinet, and a tray having a plurality of computer components mounted thereon. The tray is mounted in the cabinet such that a front panel of the tray faces outward from a front side of the cabinet opposite the rear panel of the cabinet. The computer system further includes a second port mounted on the front panel of the tray, and a first cable that electrically couples the first port and the second port. The first cable is routed within the cabinet and protrudes from the front side of the cabinet. The first port also remains coupled to the second port as the tray slides outwards from the front side of the cabinet so that the plurality of computer components substantially protrude from the front side of the cabinet. The first port and the second port are for at least one of electrical power and network connectivity.

In another innovative aspect, the invention relates to a method of servicing a computer system including a tray having a plurality of computer components including a computer component needing attention mounted thereon. The method includes sliding the tray outward from a front side of a cabinet so that the plurality of computer components substantially protrude from the front side of the cabinet, where a first cable extends from the cabinet to a first port mounted on a front panel of the tray to provide at least one of electrical power and network connectivity to the tray. The method further includes servicing the computer component needing attention and sliding the tray inward so that the plurality of computer components no longer protrudes from the front side of the cabinet. The method is performed while the plurality of computer components remain in service.

In a further innovative aspect, the invention relates to a method of upgrading a computer system including a tray having a plurality of computer components. The method includes sliding the tray outward from a front side of a cabinet so that the plurality of computer components substantially protrude from the front side of the cabinet, where a first cable extends from the cabinet to a first port mounted on a front panel of the tray to provide at least one of electrical power and network connectivity to the tray. The method further includes mounting a first computer component on the tray. The method further includes checking that the first computer component is operational, including checking that the first computer component has at least one of electrical power and network connectivity. The method further includes sliding the tray inward so that the first computer component and the plurality of computer components no longer protrude from the front side of the cabinet. The method is performed while the plurality of computer components remain in service.

### BRIEF DESCRIPTION OF THE DRAWINGS

For a better understanding of the nature and objects of the invention, reference should be made to the following detailed description taken in conjunction with the accompanying drawings, in which:

FIG. 1 illustrates a front perspective view of a computer system including a cabinet and trays mounted in the cabinet, in accordance with one embodiment of the present invention;

FIG. 2 illustrates a top perspective view of a tray including computer components mounted thereon, in accordance with one embodiment of the present invention;

FIG. 3 illustrates a rear perspective view of a computer system including a cabinet, and including fans and ports mounted on a rear panel of the cabinet, in accordance with one embodiment of the present invention;

FIG. 4 illustrates a front perspective view of a computer system including a cabinet and trays mounted in the cabinet, where cables extend from the cabinet to ports mounted on a front panel of the tray, in accordance with one embodiment of the present invention;

FIG. 5 illustrates a front perspective view of a computer system including a cabinet and a tray substantially protruding from the front side of the cabinet, where cables extend from the cabinet to ports mounted on a front panel of the tray, in accordance with one embodiment of the present invention;

FIG. 6 illustrates a phantom front perspective view of a tray mounted to a frame with a strip that latches the tray in the frame, in accordance with one embodiment of the present invention;

FIG. 7 illustrates a phantom side perspective view of the structure of FIG. 6; and

FIG. 8 illustrates a logical block diagram of power connections and network connections to trays in a cabinet, in accordance with one embodiment of the present invention.

### DETAILED DESCRIPTION OF THE INVENTION

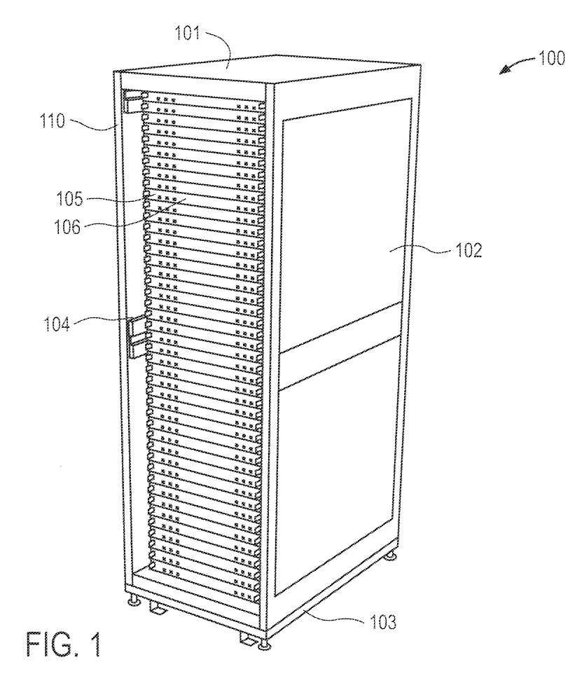

FIG. 1 illustrates a front perspective view of a computer system 100 including a cabinet 110 and trays 105 mounted in the cabinet 110, in accordance with one embodiment of the present invention. The cabinet 110 has a top panel 101, side panels 102, and a bottom panel 103. Trays 105 have front panels 106 that face outward from a front side 104 of the cabinet 110. The front side 104 of the cabinet 110 may at least partially expose front panels 106 of trays 105. In one embodiment, the front side 104 of the cabinet 110 may not be covered with a front panel to facilitate access to the trays 105, such as for servicing or replacement of the trays 105. The exposure of the front panels 106 also enhances airflow from outside the cabinet 110 toward the front panels 106 of the trays 105, or the reverse, for cooling computer components mounted on the trays 105. Alternatively, the front side 104 of the cabinet 110 may be covered with a front panel (not shown). The front panel may be used to reduce electromagnetic interference (EMI) from the cabinet 110. The front panel may also allow air to flow from outside the cabinet 110 through the front panel toward the front panels 106 of the trays 105, or the reverse. Computer components may be mounted on the trays 105. The trays 105 may be horizontally mounted in the cabinet 110, as shown in FIG. 1. Alternatively, the trays 105 may be vertically mounted in the cabinet 110. If vertically mounted, the trays 105 may be mounted in one or more vertically spaced apart bays (not shown). The trays 105 may be mounted on rails attached to side panel 102 such that the rails face trays 105 mounted in the cabinet 110, to allow the trays 105 to slide in and out of the cabinet 110.

In one embodiment, the cabinet 110 may have a height that is an integer multiple of 1U. Some examples of commonly used cabinet heights are 22U, 36U, 40U, 42U, and 44U. Each tray 105 may also have a height that is an integer multiple of 1U, such as 1U or 2U. Alternatively, each tray 105 may have a height that is not an integer multiple of 1U, such as 0.5U or 1.5U. The cabinet 110 may also have a height that is not an integer multiple of 1U, such as 43.5U or 44.5U. In one representative embodiment, the cabinet 110 may have a width of approximately 26″ and a depth of approximately 40″. Trays 105 horizontally mounted in the cabinet 110 may correspondingly have a width of approximately 19″ and a depth of approximately 31″.

Trays 105 for each type of cabinet 110 may be of a single uniform height, so that the spacing of trays 105 in each type of cabinet 110 is uniform. This has the operational advantage of enabling trays 105 for each type of cabinet 110 to be easily interchangeable. Alternatively, trays 105 of different types may be of different heights. For example, a first type of tray 105 that supports expansion cards may be of a greater height than a second type of tray 105 that does not support expansion cards.

There are various advantages of mounting computer components on trays 105 mounted in the cabinet 110, as compared to housing computer components in a chassis mounted in a rack. Some of the advantages are described here, while other advantages are described later in this description. The design of a tray may he simpler than that of a chassis, so new tray designs supporting new groupings and placement of computer components may be generated more quickly than corresponding new chassis designs. The fabrication of a tray may also be cheaper than the fabrication of a chassis because a tray may have a simpler structure and may require less material than a chassis. Moreover, EMI testing may be simplified for trays mounted in a cabinet because EMI testing may only need to be done per cabinet, rather than per chassis.

In addition, the computer components mounted on trays 105 may be exposed so that the computer components are easily accessible after sliding a tray 105 out of the cabinet 110. In contrast, a chassis housing may cover computer components mounted in the chassis. Because a tray does not require the additional structure covering the computer components mounted on the tray, it may therefore be possible to pack trays more closely together than would otherwise be possible using chassis.

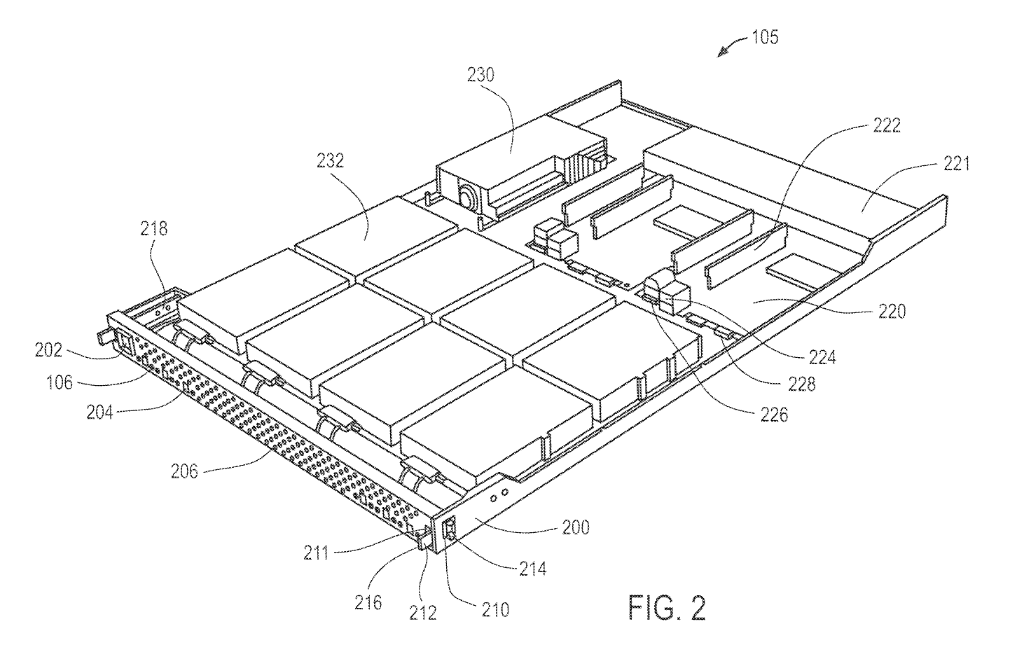

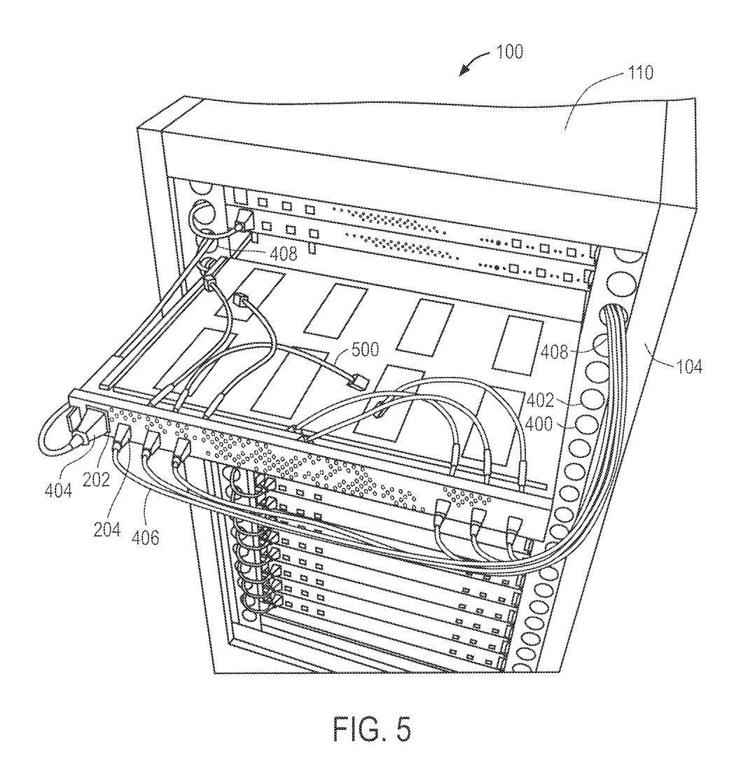

FIG. 2 illustrates a top perspective view of the tray 105 including computer components mounted thereon, in accordance with one embodiment of the present invention. The tray 105 has a front panel 106 and side panels 200. The front panel 106 includes one or more types of ports. The front panel 106 may include one or more ports 202 for electrical power. The front panel 106 may also include one or more ports 204 for network connectivity, such as Ethernet ports. In addition, the front panel 106 may include other ports that may be accessed as part of servicing or upgrading the trays 105. It is desirable for the front panel 106 to include all ports that should remain connected as the tray 105 is slid out of the cabinet 110 to facilitate servicing and/or upgrading one or more components on the tray 105 while the other components on the tray 105 remain in service, as described in more detail in the description of FIG. 5. The front panel 106 may also include perforations 206 that allow airflow through the front panel 106.

In one embodiment, the tray 105 has mounted thereon computer components including one or more printed circuit boards (PCB) 220, one or more hard disks 232, and one or more power supplies 230. The configuration of the tray 105 is flexible, and other types of computer components may also be mounted on the tray 105. For example, the tray 105 may be configured as a computer server, a storage node, and/or a switch. Each PCB 220 may have mounted thereon one or more processors 221, memory 222, and a plurality of I/O connectors. Each PCB 220 also may have mounted thereon other types of electronic components, such as application specific integrated circuits (ASICs). The types of I/O connectors may vary depending on the configuration of the PCB 220, but may include, for example, one or more network connectors 224 (such as female RJ-45 connectors), one or more USB ports 226, and one or more video ports 228 (such as DVI connectors). The I/O connectors may further include, for example, an AT connector, a PS/2 connector, a SCSI port, an ATA port, a serial port, an IEEE 1394 port, and a parallel port.

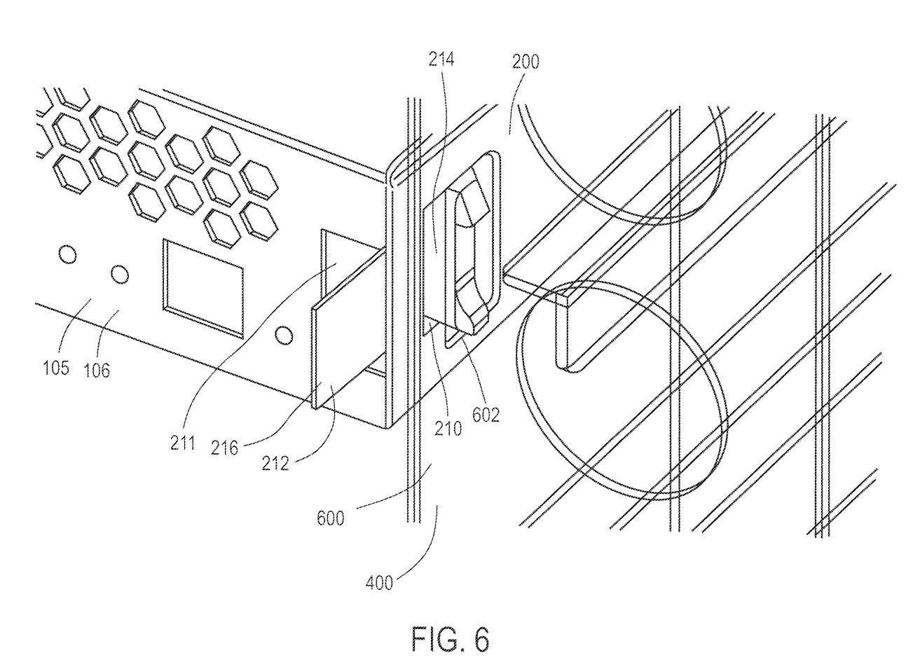

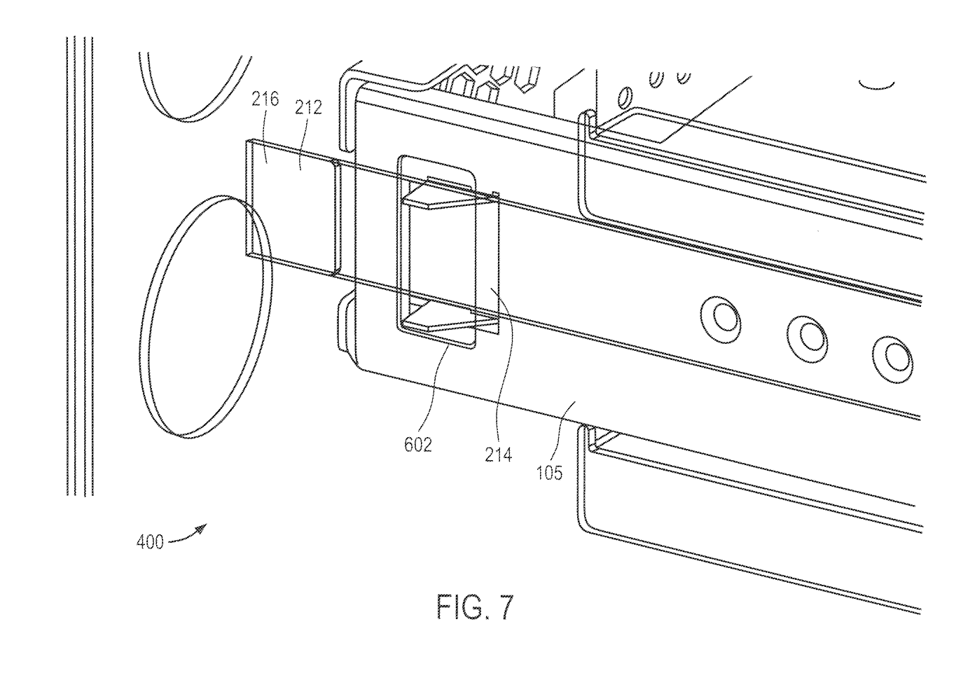

The tray 105 may include an opening 210 in each side panel 200, and an opening 211 on each side of the front panel 106. A strip 212 is mounted on each side panel 200 using, for example, one or more screws 218. Each strip 212 faces inward toward the computer components mounted on the tray 105. Each strip 212 may be a thin piece of metal with a protrusion 214 extending from a first side of each strip 212. Each strip 212 is mounted so the protrusion 214 extends through the opening 210 in the side panel 200. Each strip 212 includes a tab 216 that protrudes from the opening 211 in the front panel 106. The strips 212 are configured to serve as part of a latching mechanism to hold each tray 105 in place in the cabinet 110, so the tray 105 does not slide in and out of the cabinet 110 without human intervention. The latching mechanism is described further in FIGS. 6 and 7.

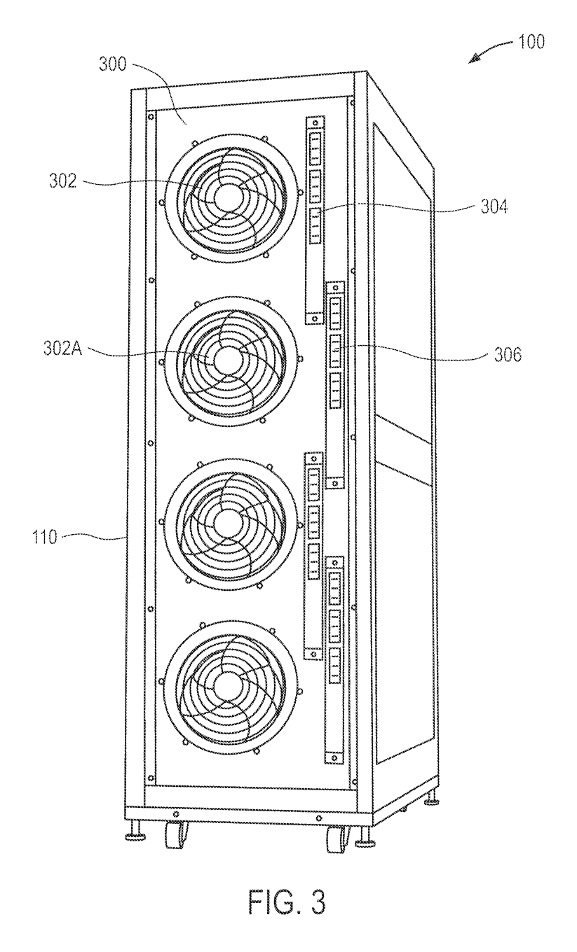

FIG. 3 illustrates a rear perspective view of the computer system 100 including the cabinet 110, and including fans 302 and ports 304 and 306 mounted on a rear panel 300 of the cabinet 110, in accordance with one embodiment of the present invention. The rear panel 300 may include one or more ports 304 for electrical power. The rear panel 300 may also include one or more ports 306 for network connectivity, such as Ethernet ports.

In one embodiment, air can be drawn out of the cabinet 110 by the fans 302. This creates a negative pressure region in the cabinet 110, such as between the trays 105, so that air travels from the environment, through the perforations 206 on the front panels 106 of the trays 105, and into the cabinet 110. In this embodiment, components on the trays 105 can be placed so, for example, components that generate the most heat are placed near the rear panel 300 on which the fans 302 are mounted. Alternatively, fans 302 can push air from the environment into the cabinet 110, and out of the cabinet 110 through the perforations 206 on the front panels 106 of the trays 105. In this embodiment, components on the trays 105 can be placed so, for example, components that generate the most heat are placed near the front panels 106.

The fans 302 are preferably at least 4U in diameter, and can eliminate the need for fans mounted on the trays 105 or in computer components mounted on the trays 105, such as power supplies 230. The increase in the size of the fans 302 as compared to the approximately 1U-diameter fans typically mounted on trays with 1U height significantly increases airflow between the trays 105 mounted in the cabinet 110, which may reduce the probability of failure of the computer components mounted on the trays 105 due to overheating. Larger fans 302 may also be more mechanically reliable than 1U fans. In addition, the placement of the fans 302 on the rear panel 300 of the cabinet 110 makes them easily replaceable in the event of a failure of one of the fans 302.

In one embodiment, the fans 302 may run at partial speed, such as 50% speed, in regular operating mode. The speed of one or more of the fans 302 may be adjusted up or down based on measurements such as temperature and/or air flow measurements at one or more locations in the cabinet 110. The failure of a fan 302A may be detected by a mechanism such as temperature and/or air flow measurements at one or more locations in the cabinet 110. In the event of such a failure, the speed of the fans 302 excluding the failed fan 302A may be adjusted up. The amount of this upward adjustment may be preconfigured and/or based on measurements such as temperature and/or air flow measurements at one or more locations in the cabinet 110. The amount of this upward adjustment may be constrained by the maximum operating speed of the fans 302. The higher speed is maintained until the failed fan 302A is replaced.

Cabinets 110 may be deployed in rows such that the rear panels 300 of the cabinets 110 face each other. This may create warm aisles between the rear panels 300 of the cabinets 110 if cooling air is exhausted from the rear panels 300, or alternatively may create warm aisles between the front sides 104 of the cabinets 110 if cooling air is exhausted from the front panels 106 of the trays 105. Alternatively, cabinets 110 may be deployed in a container with rear panels 300 facing interior walls of the container so that cooling air is exhausted into an exhaust region between the rear panels 300 and the interior walls of the container, as described in U.S. Ser. No. 11/860,685, to Coglitore et al., filed on Sep. 25, 2007, incorporated by reference herein in its entirety. The heated air may be cooled by any of a variety of known cooling systems for removing heat from air, certain embodiments of which are described in U.S. Ser. No. 11/860,685.

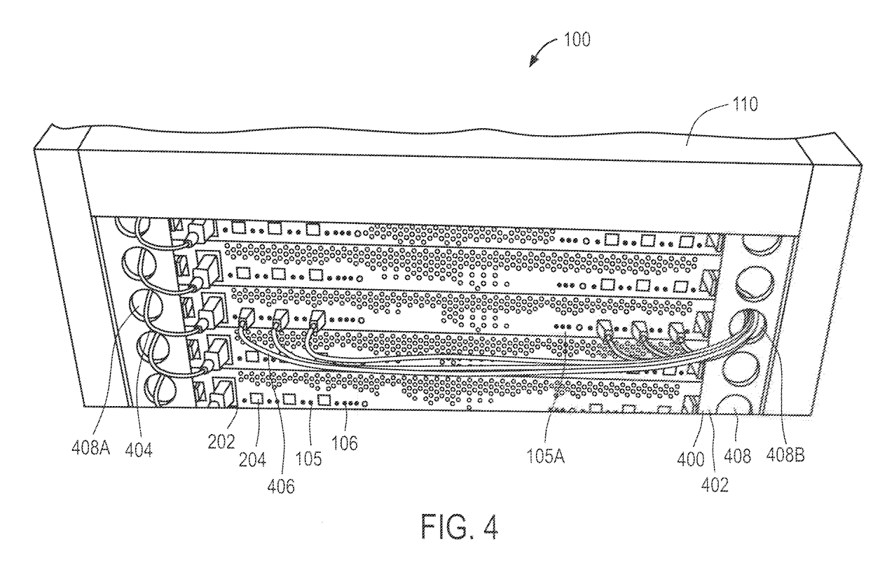

FIG. 4 illustrates a front perspective view of a computer system 100 including the cabinet 110 and trays 105 mounted in the cabinet 110, where cables 404 and 406 extend from the cabinet 110 to ports 202 and 204 mounted on the front panel 106 of each tray 105, in accordance with one embodiment of the present invention. Each cable 404 may electrically couple port 304 on the rear panel 300 to port 202 on the front panel 106 of the tray 105, so as to provide electrical power to port 202. Each cable 406 may also electrically couple port 306 on the rear panel 300 to port 204 on the front panel 106 of the tray 105, so as to provide network connectivity to port 204. The cables 404 and 406 may protrude from the front side 104 of the cabinet 110, and may be routed within the cabinet 110.

The cabinet 110 may include a frame 400 on which each tray 105 is mounted such that the front panel 106 of the tray 105 faces outward from a front panel 402 of the frame 400. The trays 105 may be mounted on rails attached to the frame 400 to allow the trays 105 to slide in and out of the cabinet 110. The front panel 402 of the frame 400 may include one or more openings 408. Each opening 408 may be positioned adjacent to one of the trays 105. In addition, a tray 105A may have one opening 408A adjacent to a first side of the tray 105A, and another opening 408B adjacent to a second side of the tray 105A opposite the first side. In one embodiment, the one or more cables 404 to be connected to the tray 105A may be routed through the opening 408A, and the one or more cables 406 to be connected to the tray 105A may be routed through the opening 408B.

FIG. 5 illustrates a front perspective view of the computer system 100 including the cabinet 110 and the tray 105 substantially protruding from the front side 104 of the cabinet 110, where the cables 404 and 406 extend from the cabinet 110 to the ports 202 and 204 mounted on the front panel 106 of the tray 105, in accordance with one embodiment of the present invention. The ports 202 and 204 remain coupled to ports 304 and 306, respectively, on the rear panel 300 as the tray 105 slides outwards from the front side 104 of the cabinet 110, so that computer components on the tray 105 can be accessed from the front side 104 of the cabinet 110. In one embodiment, the cabinet 110 includes service loops for cables 404 and 406 that include an extra length of cable. As the tray 105 slides outwards from the front side 104 of the cabinet 110, the extra lengths of cables 404 and 406 can be unwound so that cables 404 and 406 remain coupled to the ports 202 and 204, respectively. A spring loaded system may be provided to facilitate the retraction of the extra lengths of cables 404 and 406 as the tray slides back into the cabinet 110. Alternatively, the extra lengths of cables 404 and 406 may retract as a result of the motion of tray 105 sliding back into the cabinet 110, in combination with gravity. The extra lengths of cables 404 and 406 may also be manually fed back into the service loops. The cables 404 and 406 can be disengaged from the ports 202 and 204, respectively, to enable the tray 105 to be fully removed from the cabinet 110.

In one embodiment, cables 500 may extend from ports 202 and/or 204 to a port mounted on one or more of the computer components mounted on the tray 105. For example, cables 500 can plug into network connectors 224 of the motherboard 220. Alternatively, power may be distributed over rails (not shown) to the computer components on the tray 105. If a tray 105 is upgraded by mounting an additional computer component on the tray 105, one or more cables 500 may be plugged into connectors on the additional component as part of the upgrade process.

There are various operational and maintainability advantages of the cabling configuration shown in FIGS. 4 and 5 as applied to trays 105 mounted in the cabinet 110. To service or upgrade computer components on a tray, the components can be accessed by simply sliding the tray out of the cabinet. In contrast, in a conventional rack-based system, more effort is typically required, as a computer chassis including the computer components typically needs to be unscrewed from the rack frame or from sliders attached to the rack frame. Then, the lid of the computer chassis typically needs to be unscrewed from the chassis frame to access the computer components in the chassis.

In addition, the cabling configuration shown in FIGS. 4 and 5 as applied to trays 105 mounted in the cabinet 110 enables servicing and/or upgrade of components on a tray 105 while other unaffected components on the tray 105 remain in service. In the embodiment of FIG. 5, the front panel 106 includes port 202 for power connectivity and ports 204 for network connectivity. An outside power source is connected to port 304, and a data connection for the cabinet 110 is connected to port 306. External connections to ports 304 and 306 are not typically disturbed as part of servicing and/or upgrading trays 105. Since cables 404 and 406 can extend and thus can remain connected to ports 202 and 204 as the tray 105 is slid out of the cabinet 110, the tray 105 can remain electrically coupled to ports 304 and 306. Thus, the tray 105 can maintain power and network connectivity as it is slid out of the cabinet 110, and thus computer components on the tray 105 can remain in service. If additional types of connections are needed for components on the tray 105 to remain in service, this cabling approach can be used so that the tray 105 can also maintain the additional types of connectivity as the tray 105 is slid out of the cabinet 110.

The cabling configuration shown in FIGS. 4 and 5 as applied to trays 105 mounted in the cabinet 110 also enables flexible and convenient servicing and/or upgrade of computer components on the trays 105. Since cabling needed as part of this servicing and/or upgrade is accessible from the front side 104 of the cabinet 110, there is no need, for example, to access the rear of the cabinet 110 or to remove the rear panel 300 of the cabinet 110 to access cables in the rear of the cabinet 110. This can avoid taking one or more fans 302 on the rear panel 300 out of operation, which is important to maintain an acceptable operating temperature for trays 105 in embodiments in which separate fans are not provided for cooling the trays 105. If servicing or upgrade requires power to be shut off for a particular tray 105A, this can easily be done from the front side 104 of the cabinet 110, without affecting the operation of the other trays 105. Similarly, network connectivity can be removed and restored for a portion of a tray 105A without affecting other portions of the tray 105A or other trays 105.

As part of servicing or upgrade, it may be desirable to check that a computer component is operational prior to sliding a tray 105 back into the cabinet 110. This checking may be done using any of the many well-known techniques for testing computer components, such as testing whether electrical inputs and outputs of the components are in valid ranges, or whether electrical outputs of the components assume expected values for particular electrical input values.

FIG. 6 illustrates a front perspective view of the tray 105 with the frame 400 on which the tray 105 is mounted rendered transparently to show the strip 212 that latches the tray 105 in the frame 400, in accordance with one embodiment of the present invention. To latch the tray 105 in the frame 400, the protrusion 214 in the strip 212 extends through an opening 602 in a side panel 600 of the frame 400 as the tray 105 is pushed back into the cabinet 110. To unlatch the tray 105 from the frame 400, the tabs 216 on one or both sides of the front panel 106 of the tray 105 may be pushed in a direction pointing away from the side panel 602. By pushing the tabs 216, the protrusions 214 of the strips 212 are withdrawn from the openings 602, enabling the tray 105 to be pulled out of the cabinet 110.

FIG. 7 illustrates a side perspective view of the tray 105 with the frame 400 on which the tray 105 is mounted rendered transparently to show the strip 212 that latches the tray 105 in the frame 400, in accordance with one embodiment of the present invention.

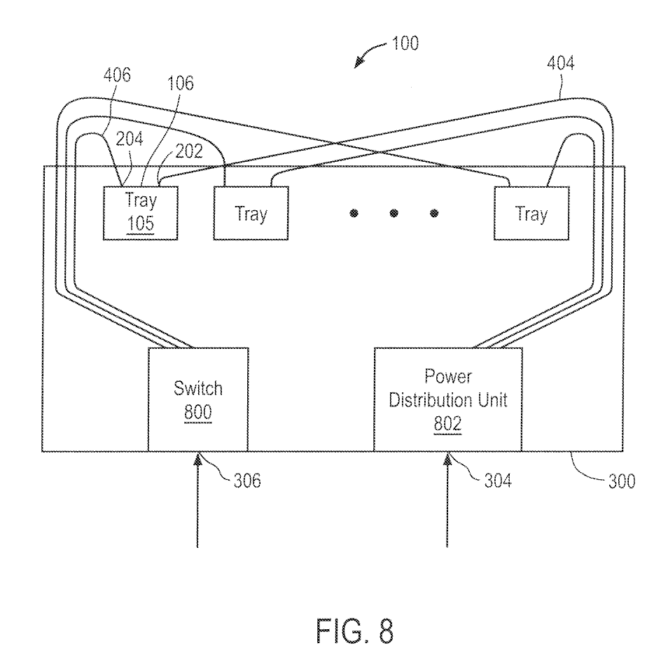

FIG. 8 illustrates a logical block diagram of power connections 404 and network connections 406 to trays 105 in the cabinet 110, in accordance with one embodiment of the present invention. In this embodiment, one or more external power sources is connected to ports 304. The external power sources may, for example, be 110V/220V AC sources or 48V DC sources. A power distribution unit (PDU) 802 distributes the input electrical power to one or more trays 105 via cables 404 that extend from the PDU 802 to ports 202 on the trays 105. The power supply 230 on each tray 105 may be a rectifier that converts an AC input to a DC output. In addition, network connectivity is provided to an uplink port 306 of a switch 800. The switch 800 provides network connectivity to the trays 105 via cables 406 that extend from the switch 800 to ports 204 on the trays 105.

The figures provided are merely representational and may not be drawn to scale. Certain proportions thereof may be exaggerated, while others may be minimized. The figures are intended to illustrate various implementations of the invention that can be understood and appropriately carried out by those of ordinary skill in the art.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

What is claimed is:

1. A computer system, comprising:
a cabinet;
a first port mounted on a rear panel of the cabinet;
a tray having a plurality of computer components mounted thereon, wherein the tray is mounted in the cabinet such that a front panel of the tray faces outward from a front side of the cabinet opposite the rear panel of the cabinet;
a second port mounted on the front panel of the tray; and
a first cable that electrically couples the first port and the second port, wherein the first cable is routed within the cabinet and protrudes from the front side of the cabinet;
wherein the first port remains coupled to the second port as the tray slides outwards from the front side of the cabinet so that the plurality of computer components substantially protrude from the front side of the cabinet; and
wherein the first port and the second port are for at least one of electrical power and network connectivity.

2. The computer system of claim 1, wherein:
the first port and the second port are for electrical power; and
the first cable extends from a power distribution unit mounted in the cabinet to the second port on the front panel of the tray.

3. The computer system of claim 1, wherein:
the first port and the second port are for network connectivity; and
the first cable extends from a switch mounted in the cabinet to the second port on the front panel of the tray.

4. The computer system of claim 3, further comprising a second cable that extends from the second port to a third port on one of the plurality of computer components.

5. The computer system of claim 3, further comprising a second cable that electrically couples the first port and the second port, wherein the second cable extends from the first port mounted on the rear panel of the cabinet to the switch mounted in the cabinet.

6. The computer system of claim 2, further comprising:
a third port for network connectivity mounted on the rear panel of the cabinet;
a fourth port for network connectivity mounted on the front panel of the tray; and
a second cable that electrically couples the third port and the fourth port, wherein:
the second cable is routed within the cabinet and protrudes from the front side of the cabinet; and
the third port remains coupled to the fourth port as the tray slides outwards from the front side of the cabinet so that the plurality of computer components substantially protrude from the front side of the cabinet.

7. The computer system of claim 1, wherein:
the cabinet includes a frame on which the tray is mounted such that a front panel of the tray faces outward from a front panel of the frame; and
the front panel of the frame includes a first opening through which the first cable is routed.

8. The computer system of claim 7, further comprising:
a side panel of the tray including a second opening;
a side panel of the frame including a third opening;
a strip mounted on a first side of the side panel that faces inward toward the computer components mounted on the tray, wherein:
the strip includes a tab that protrudes from the front panel of the tray; and
the strip includes a protrusion that extends through the second opening and the third opening to latch the tray in the frame.

9. The computer system of claim 1, wherein the computer components mounted on the tray include:
a plurality of printed circuit boards, wherein a processor, memory, and I/O connectors are mounted on each of the plurality of printed circuit boards;
a plurality of hard disks; and
a power supply.

10. The computer system of claim 1, further comprising a fan mounted on a rear panel of the cabinet, wherein the diameter of the fan is at least four times larger than the height of the tray.

11. A method of servicing a computer system including a tray having a plurality of computer components including a computer component needing attention mounted thereon, comprising:
while the plurality of computer components other than the computer component needing attention remain in service:
sliding the tray outward from a front side of a cabinet so that the plurality of computer components substantially protrude from the front side of the cabinet, wherein a first cable extends from the cabinet to a first port mounted on a front panel of the tray to provide at least one of electrical power and network connectivity to the tray;
servicing the computer component needing attention; and
sliding the tray inward so that the plurality of computer components no longer protrudes from the front side of the cabinet.

12. The method of claim 11, further comprising:
removing at least one of electrical power and network connectivity to the computer component needing attention prior to servicing the computer component; and
restoring at least one of electrical power and network connectivity to the computer component after servicing the computer component.

13. The method of claim 12, wherein restoring at least one of electrical power and network connectivity to the computer component includes:
coupling the computer component to a switch mounted in the cabinet; and
coupling the computer component to a power distribution unit mounted in the cabinet.

14. The method of claim 11, wherein the first cable retracts into an opening in a frame of the cabinet in response to the tray sliding into the cabinet.

15. The method of claim 11, wherein the computer components mounted on the tray include:
a plurality of printed circuit boards, wherein a processor, memory, and 1/0 connectors are mounted on each of the plurality of printed circuit boards;
a plurality of hard disks; and
a power supply.

16. A method of upgrading a computer system including a tray having a plurality of computer components, comprising:
while the plurality of computer components remain in service:
sliding the tray outward from a front side of a cabinet so that the plurality of computer components substantially protrude from the front side of the cabinet, wherein a first cable extends from the cabinet to a first port mounted on a front panel of the tray to provide at least one of electrical power and network connectivity to the tray;
mounting a first computer component on the tray;
checking that the first computer component is operational, including checking that the first computer component has at least one of electrical power and network connectivity; and
sliding the tray inward so that the first computer component and the plurality of computer components no longer protrude from the front panel of the cabinet.

17. The method of claim 16, further comprising:
coupling the first computer component to a switch mounted in the cabinet; and
coupling the first computer component to a power distribution unit mounted in the cabinet.

18. The method of claim 16, wherein the first cable retracts into an opening in a frame of the cabinet in response to the tray sliding into the cabinet.

19. The method of claim 16, wherein the computer components mounted on the tray include:
a plurality of printed circuit boards, wherein a processor, memory, and I/O connectors are mounted on each of the plurality of printed circuit boards;
a plurality of hard disks; and
a power supply.
